(19) United States
(12) Patent Application Publication
(10) Pub. No.: US 2007/0193622 A1
(43) Pub. Date: Aug. 23, 2007

(54) Laminate Type Thin-Film Solar Cell And Method For Manufacturing The Same

(76) Inventor: Hironobu Sai, Kyoto-shi (JP)

Correspondence Address: RABIN & Berdo, PC, 1101 14TH STREET, NW, SUITE 500, WASHINGTON, DC, 20005, US

(21) Appl. No.: 10/594,631

(22) PCT Filed: Mar. 30, 2005
(86) PCT No.: PCT/JP05/06172

§ 371 Date: Sep. 28, 2006

(30) Foreign Application Priority Data
Mar. 31, 2004 (JP) 2004-103933

(51) Int. Cl. H01L 31/00

(52) U.S. Cl. 136/252

(57) ABSTRACT

A laminate type thin-film solar cell which can convert sunlight efficiently into electric power and be formed in multi-laminate structure without limitation in selecting a semiconductor material, and be excellent in conversion efficiency, and a production method therefor are provided. A first photoelectric conversion unit including a first semiconductor lamination portion (1a) made of a semiconductor having a first band gap energy and a first pair of electrodes (13, 14) is provided on a substrate (4), and a second photoelectric conversion unit including a second semiconductor lamination portion (2a) made of a semiconductor having a second band gap energy and a second pair of electrodes (23, 24) is stuck thereon. A third photoelectric conversion unit including a third semiconductor lamination portion (3a) made of a semiconductor having a third band gap energy and a third pair of electrodes (33, 34) may be stuck thereon, and as many conversion units as desired can be stuck.

### FIELD OF THE INVENTION

The present invention relates to a laminate type thin-film solar cell in which a plurality of photoelectric conversion units made of semiconductor films are laminated by sticking, and relates to a method for manufacturing the same. More particularly, the present invention relates to a laminate type thin-film solar cell capable of photoelectric conversion in high efficiency by solving a problem such as lattice defects or the like caused by a difference in lattice constants and by reducing a conversion loss caused by a tunnel junction between a plurality of photoelectric conversion units, while converting sunlight of a wide wavelength spectrum into electric power in high efficiency, and relates to a method for manufacturing the same.

### BACKGROUND OF THE INVENTION

In a solar cell by the prior art, electrodes are formed on both sides of a p-n junction formed of, for example, silicon semiconductor, and photo-electromotive force generated at both ends of the p-n junction by traveling of electrons and holes, which are generated in a pair creation by light, by an internal electric field of a junction part, is taken out from the both electrodes. Here, as a band gap energy of silicon is 1.1 eV, which corresponds to a region near infrared ray, an efficiency of utilizing light energy is approximately 50% in principle in case of receiving light near visible ray (2 eV). A theoretical efficiency of a solar cell made of a single crystal of silicon is 45% at most by the above-described efficiency in utilizing light energy, and a practical efficiency in consideration of other loss is approximately 28%.

On the other hand, as shown, for example, in FIG. 5, a solar cell of a tandem type has been studied which is formed by laminating an upper cell 34 made of InGaP and a lower cell 32 made of GaAs, through a tunnel junction layer 33 made of GaAs, in order to solve the above-described problem of a conversion efficiency. Namely, the lower cell 32 formed of a p-GaAs layer 321, an n⁺-GaAs layer 322 and an n⁺-AlGaAs layer 323, is laminated on a substrate 31 made of p⁺-GaAs; the tunnel junction layer 33 formed of an n⁺⁺-GaAs layer 331 and a p⁺⁺-GaAs layer 332, thereon; and the upper cell 34 formed of a p-InGaP layer 341, an n⁺-InGaP layer 342 and an n⁺-AlInP layer 343, thereon, and electrodes 35 and 36 made of Au are provided on a surface of the upper cell and on a back surface of the semiconductor substrate 31 respectively (cf. for example, PATENT DOCUMENT 1).

PATENT DOCUMENT 1: Japanese Patent Application Laid-Open No. HEI8-162649 (FIG. 5)

### DISCLOSURE OF THE INVENTION

### Problem to be Solved by the Present Invention

As described above, in case of forming a tandem structure, in which light of wide range of wavelength can be absorbed, by laminating semiconductor materials having different band gap energies, since a portion of a tunnel junction is necessary, a problem occurs such that a conversion efficiency remains to be approximately 29% by a loss generated in the tunnel junction or the like.

A solar cell formed by laminating three units of InGaP, GaAs and InGaAs has been studied, but a semiconductor layer of a good crystal structure can not be grown because lattice matching between GaAs and InGaAs can not be performed, although lattice matching between InGaP and GaAs can be performed rather easily. Therefore, there is a problem in forming a multi-lamination structure, such that a solar cell having a sufficiently high conversion efficiency can not be obtained because of a limitation in selecting materials. By the way, a theoretical conversion efficiency is supposed to be approximately 80% in the lamination structure of the above-described three units, if no conversion loss caused by a tunnel junction or lattice defects exists.

The present invention is directed to solve the above-described problems and an object of the present invention is to provide a laminate type thin-film solar cell which can convert sunlight efficiently into electric power and be formed in multi-laminate structure without limitation in selecting a semiconductor material, and be excellent in conversion efficiency.

Another object of the present invention is to provide a method for manufacturing a laminate type thin-film solar cell in which an electrode of each photoelectric conversion unit can be simply formed and in which a crystal structure of each semiconductor layer can be also maintained in good condition, even if lattice constants of semiconductor layers are different.

### Means For Solving the Problem

A laminate type thin-film solar cell according to the present invention includes: a substrate; a first photoelectric conversion unit formed on the substrate, the first photoelectric conversion unit including a first semiconductor lamination portion made of a semiconductor having a first band gap energy and a first pair of electrodes which are formed on at least a part of each of both surfaces of the first semiconductor lamination portion and connected electrically thereto; and a second photoelectric conversion unit formed on the first photoelectric conversion unit, the second photoelectric conversion unit including a second semiconductor lamination portion made of a semiconductor having a second band gap energy and a second pair of electrodes which are formed on at least a part of each of both surfaces of the second semiconductor lamination portion and connected electrically thereto.

The electrodes of each unit can be easily formed by the structure in which one of each of the first and second pairs of electrodes is formed on a part of a semiconductor layer of each of the first and second photoelectric conversion units, the part being exposed by the level difference which is formed by sticking the first and second photoelectric conversion units with a displacement. Further, the first and second pairs of electrodes may be formed on surroundings of both surfaces of each of the first and second photoelectric conversion units, and the first and second photoelectric conversion units may be stuck, by putting one on the other, at faced parts of one of the first pair of electrodes and one of the second pair of electrodes so as to be connected electrically in series.

The solar cell may be formed in a structure further including; a third photoelectric conversion unit formed on a surface of the second photoelectric conversion unit, the third photoelectric conversion unit including a third semiconductor lamination portion made of a semiconductor having a third band gap energy and a third pair of electrodes which are formed on at least a part of each of both surfaces of the third semiconductor lamination portion and connected electrically thereto; and a forth photoelectric conversion unit formed on a surface of the third photoelectric conversion unit, the forth photoelectric conversion unit including a forth semiconductor lamination portion made of a semiconductor having a forth band gap energy and a forth pair of electrodes formed on at least a part of each of both surfaces of the forth semiconductor lamination portion and connected electrically thereto. By this structure, light can be converted into electric power at wider range of wavelength and efficiency of converting light into electric power.

The semiconductor layers of the first, second, third and forth photoelectric conversion units are made of compound semiconductors composed of elements selected from Mg, O, Zn, Se, Al, Ga, As, P and N, such as, for example, InₓGa₁₋ₓAs (0≦x≦1), In_{z}(Ga_{y}Al_{1-y})_{1-z}P (0≦y≦1, 0<z<1) or the like, and semiconductors composed of a simple substance or a compound of elements selected from Si, Ge and C. A photoelectric conversion unit formed of a semiconductor layer having a large band gap energy is preferably set on a surface side irradiated by light, then proper combination may be employed.

A method for manufacturing a laminate type thin-film solar cell includes the steps of: (a) forming a second semiconductor lamination portion, which composes a second photoelectric conversion unit, through an easily-oxidized compound layer with matching in crystal structure to a substrate for growing semiconductor layers on the substrate; (b) sticking only the second semiconductor lamination portion on a temporary substrate, by sticking a top face of the second semiconductor lamination portion on a temporary substrate and by removing the substrate for growing by dissolving an oxidized layer formed by oxidizing the easily-oxidized compound layer; (c) forming a first semiconductor lamination portion, which composes the first photoelectric conversion unit through an easily-oxidized compound layer with matching in crystal structure to a substrate for growing semiconductor layers on the substrate; (d) sticking only the first semiconductor lamination portion left, by sticking the first semiconductor lamination portion on a surface of the second semiconductor lamination portion stuck on the temporary substrate, so as to expose a part of the second semiconductor lamination portion by displacement and by removing the substrate for growing by dissolving an oxidized layer formed by oxidizing the easily-oxidized compound layer; (e) forming an electrode on the exposed surface of at least the second semiconductor lamination portion by depositing a metal film from a top surface side of the first semiconductor lamination portion; (f) removing the temporary substrate after sticking a real substrate on a surface of the first semiconductor lamination portion; and (g) forming an electrode on an exposed surface, which surface is a contacted surface of the first semiconductor lamination portion contacted with the second semiconductor lamination portion, by depositing a metal film from a surface side of the second semiconductor lamination portion.

A method for manufacturing the laminate type thin-film solar cell may include the steps of: (a) forming a first semiconductor lamination portion, which composes a first photoelectric conversion unit, through an easily-oxidized compound layer with matching in crystal structure to a substrate for growing semiconductor layers on the substrate, and forming one of the first pair of electrodes on a part of the first semiconductor lamination portion; (b) sticking only the first semiconductor lamination portion on a real substrate, by sticking a top face of the first semiconductor lamination portion on the real substrate such that an electrode formed on the real substrate connects to the one of the first pair of electrodes of the first photoelectric conversion unit, and by removing the substrate for growing by dissolving an oxidized layer formed by oxidizing the easily-oxidized compound layer; (c) forming a second semiconductor lamination portion, which composes a second photoelectric conversion unit through an easily-oxidized compound layer with matching in crystal structure to a substrate for growing semiconductor layers on the substrate, and forming one of a second pair of electrodes on a part of a surface of the second semiconductor lamination portion; (d) ticking only the second semiconductor lamination portion, by forming another electrode of the first pair of electrodes on a part of an exposed surface of the first semiconductor lamination portion stuck on the real substrate, by sticking a top surface of the second semiconductor lamination portion such that the another electrode of the first pair of electrodes connects to the one of the second pair of electrodes of the second semiconductor lamination portion, and by removing the substrate for growing by dissolving an oxidized layer formed by oxidizing the easily-oxidized compound layer; and (e) forming another electrode of the second pair of electrodes on a part of an exposed surface of the second semiconductor lamination portion on the real substrate.

It is preferable that the easily-oxidized compound layer is made of a material represented by AlᵤGa₁₋ᵤAs (0.5≦u≦1) or AlᵥIn₁₋ᵥAs (0.5≦v≦1), because lattice matching between the substrate and the semiconductor lamination portion can be obtained easily, and because the semiconductor lamination portion can be separated by oxidizing the easily-oxidized compound layer easily.

### EFFECT OF THE INVENTION

According to the present invention, since a pair of electrodes is connected to each of a plurality of photoelectric conversion units, light of wide range of wavelength can be converted into electric power by joining the plurality of photoelectric conversion units, and by connecting the electrodes so that the plurality of photoelectric conversion units are connected in series. Moreover, since a lamination structure of the plurality of photoelectric conversion units can be formed not by continuous growth of semiconductor layers but by sticking, a lamination structure can be obtained without problems of occurrence of lattice defects caused by lattice mismatching, even if photoelectric conversion units are formed of semiconductor layers having different band gap energies and different lattice constants. As a result of this, light of wide range of wavelength can be converted into electric power and a laminate type thin-film solar cell of little waste and high efficiency can be obtained.

And by the method according to the present invention, as a plurality of photoelectric conversion units are laminated by sticking, semiconductor lamination portions of each photoelectric conversion unit can be stuck with displacement in sticking. Then, the electrodes of each unit can be formed simultaneously and very simply by depositing a metal layer or the like on a part exposed by the level difference formed by sticking with displacement by a vacuum evaporation technique. As a result, a solar cell operating in ranges of a plurality of wavelength regions can be obtained easily only by connecting the electrodes in series.

### BRIEF DESCRIPTION OF THE DRAWINGS

FIG. 1 is a cross-sectional view explaining an embodiment of the solar cell according to the present invention.

FIGS. 2A to 2C are figures explaining a manufacturing process of the solar cell shown in FIG. 1.

FIGS. 3D to 3H are figures explaining a manufacturing process of the solar cell shown in FIG. 1.

FIGS. 4A to 4F are figures explaining another manufacturing process of the solar cell according to the present invention shown in FIG. 1.

FIG. 5 is a figure explaining a structure of a tandem type solar cell.

### EXPLANATION OF LETTERS AND NUMERALS

1: first photoelectric conversion unit
1a: first semiconductor lamination portion
2: second photoelectric conversion unit
2a: second semiconductor lamination portion
3: third photoelectric conversion unit
3a: third semiconductor lamination portion
4: substrate
13, 14: first pair of electrodes
23, 24: second pair of electrodes
33, 34: third pair of electrodes

### THE BEST EMBODIMENT OF THE PRESENT INVENTION

An explanation will be given below of a laminate type thin-film solar cell and a method for manufacturing the same according to the present invention in reference to FIGS. 1 to 3. The laminate type thin-film solar cell according to the present invention includes a first photoelectric conversion unit 1 formed on the substrate 4 and a second photoelectric conversion unit 2 formed on the first photoelectric conversion unit 1. The first photoelectric conversion unit 1 includes a first semiconductor lamination portion 1a (11, 12) made of a semiconductor having a first band gap energy and a first pair of electrodes 13 and 14 which are formed on at least a part of each of both surfaces of the first semiconductor lamination portion 1a and connected electrically thereto. The second photoelectric conversion unit 2 includes a second semiconductor lamination portion 2a (21, 22) made of a semiconductor having a second band gap energy and a second pair of electrodes 23 and 24 which are formed on at least a part of each of both surfaces of the second semiconductor lamination portion 2a and connected electrically thereto.

In an example shown in FIG. 1, a third photoelectric conversion unit 3 is formed on a surface of the second photoelectric conversion unit 2. The third photoelectric conversion unit 3 includes a third semiconductor lamination portion 3a (31, 32) made of a semiconductor having a third band gap energy and a third pair of electrodes 33 and 34 which are formed on at least a part of each of both surfaces of the third semiconductor lamination portion 3a and connected electrically thereto. Photoelectric conversion units can be stuck as many as desired and a desired range of wavelength can be covered.

In the example shown in FIG. 1, the first photoelectric conversion unit 1 is formed by sticking the first semiconductor lamination portion 1a (11, 12) on, for example, a p⁺-type silicon substrate 4, the first semiconductor lamination portion 1a is formed of a p-type layer 11 and an n-type layer 12 made of InₓGa₁₋ₓAs (0≦x≦1, for example x=0.7) which are formed in a thickness of approximately 0.5 to 3 μm and with an impurity density of approximately 1×10¹⁵ to 1×10¹⁷ cm⁻³, by forming a p-n junction layer by an epitaxial growth technique. The first photoelectric conversion unit 1 is formed by forming one electrode 13 on a back surface of the substrate 4 which is electrically connected to the p-type layer 11 and by forming another electrode 14 on a part of a surface of the n-type layer 12. In the example shown in FIG. 1, a silicon substrate of a semiconductor is used as the substrate 4, and the one electrode 13 is formed on the back surface of the substrate 4, but the one electrode 13 can be formed on a junction plane with the substrate 4 and can be taken out to a surface of the substrate 4. The electrodes 13, 14 are formed on a desired region and in a thickness of 0.2 to 1 μm or the like, by forming a layer of metal such as, for example, Au or the like by the vacuum evaporation technique or the like. The another electrode 14 can be formed all together, as described later, by forming electrodes of one side of the plurality of photoelectric conversion units by forming metal layers, after sticking a plurality of semiconductor lamination portions for photoelectric conversion units.

In a semiconductor InₓGa₁₋ₓAs (for example, x=0.7) of the first semiconductor lamination portion 1a whose band gap energy of approximately 0.6 eV, electrons and holes generated by pair creation caused by light accompanied with irradiation of light having a wavelength of approximately 0.84 to 2 μm, move by an internal electric field of the junction, and electric voltage can be obtained from both electrodes 13 and 14 by photo-electromotive force generated at both ends of p-n junction. As a semiconductor lamination portion is not limited to the lamination structure, shown in the example, of the p-type layer 11 and the n-type layer 12, a structure of p-i-n type where an i layer is interposed between the two layers can be used. An up-and-down relationship of an n-type layer and a p-type layer can be reversed.

A binding agent for sticking with the substrate 4 is necessary to be a conductive material, for example, such as AuGeNi, in case, as described above, of forming the one electrode 13 on the back surface of the substrate 4, but non-conductive material such as polyimide may be used in case of forming the one electrode by taking out a metal layer formed on the semiconductor layer (p-type layer) to the surface of the substrate. As the substrate, a semiconductor like in this case, a metal plate or a non-conductive substrate can be available and a material transparent or not can be used. A material is selected according to an object in forming electrodes.

In the example shown in FIG. 1, although the first photoelectric conversion unit 1 is stuck on the substrate 4 after being stuck with other photoelectric conversion units 2 and 3, an epitaxial growth on the substrate 4 can be performed directly in case that the substrate 4 is a semiconductor substrate and that the first semiconductor lamination portion 1a has no problem in a lattice matching.

In the example shown in FIG. 1, the second photoelectric conversion unit 2 is formed by sticking the second semiconductor lamination portion 2a on the first photoelectric conversion unit 1 with a little displacement. The second semiconductor lamination portion 2a is formed of a p-type layer 21 and an n-type layer 22 made of GaAs semiconductor which are formed in a thickness of approximately 0.5 to 3 μm and with an impurity density of approximately 1×10¹⁵ to 1×10¹⁹ cm⁻³, by forming a p-n junction layer by the epitaxial growth technique. The second photoelectric conversion unit 2 is formed by forming one electrode 23 on a part of a surface of the p-type layer 21 and by forming another electrode 24 on a part of a surface of the n-type layer 22. This pair of electrodes 23 and 24 is formed in same manner as the electrode of the first photoelectric conversion unit 1 as described above. In this case, a semiconductor lamination portion can be formed in a p-i-n structure.

In a semiconductor GaAs of the second semiconductor lamination portion 21 and 22 whose band gap energy of approximately 1.89 eV, electrons and holes generated by pair creation caused by light accompanied with irradiation of light having a wavelength of approximately 650 to 840 nm, move by an internal electric field of the junction, and electric voltage can be obtained from both electrodes 23, 24 by photo-electromotive force generated at both ends of p-n junction. The semiconductor layers 21 and 22 of the second semiconductor lamination portion 2a can be joined with InₓGa₁₋ₓAs having a different lattice constant by peeling off a thin film lamination portion formed on other GaAs substrate by epitaxial growth, as described later.

In the example shown in FIG. 1, the third photoelectric conversion unit 3 is formed by sticking the third semiconductor lamination portion 3a on the second photoelectric conversion unit 2 with a little displacement. The third semiconductor lamination portion 3a is formed of a p-type layer 31 and an n-type layer 32 made of compound semiconductors composed of elements selected from Mg, 0, Zn, Se, Al, Ga, As, P and N such as, for example, InₓGa₁₋ₓAs (0≦x≦1), In_{z}(Ga_{y}Al_{1-y})_{1-z}P (0≦y≦1, 0≦z≦1) or the like, and semiconductors composed of a simple substance or a compound of elements selected from Si, Ge and C, which are formed in a thickness of approximately 0.5 to 3 μm and with an impurity density of approximately 1×10¹³ to 1×10¹⁷ cm⁻³, by forming a p-n junction layer by the epitaxial growth technique. The third photoelectric conversion unit 3 is formed by forming one electrode 33 on a part of a surface of the p-type layer 31 and by forming another electrode 34 on a part of a surface of the n-type layer 32. This pair of electrodes 33 and 34 is formed in same manner as the electrode of the second photoelectric conversion unit 2 as described above or may be formed simultaneously after sticking each photoelectric conversion unit. In this case, a semiconductor lamination portion can be formed in a p-i-n structure.

In a semiconductor In_{0.49}(Ga_{y}Al_{1-y})_{0.51}P (for example, y=1) of the third semiconductor lamination portion 3a (31, 32) whose band gap energy of approximately 1.89 eV, electrons and holes generated by pair creation caused by light accompanied with irradiation of light having a wavelength of approximately 200 to 660 nm, move by an internal electric field of the junction, and electric voltage can be obtained from a pair of electrodes 33 and 34 by photo-electromotive force generated at both ends of p-n junction. The semiconductor layers 31 and 32 of the semiconductor lamination portion 3a can be stuck to the second semiconductor lamination portion 2a with displacement in order to form electrodes 33 and 34 easily by peeling off the semiconductor lamination portion formed on other GaAs substrate by epitaxial growth and sticking, as described later.

Photo-electromotive forces generated at each photoelectric conversion unit 1, 2 and 3 are connected in series, by laminating the first to third photoelectric conversion units 1, 2 and 3, and by connecting the first to third pairs of electrodes so that p-n junctions of each unit are in series, therefore, a total of the photo-electromotive forces generated in each photoelectric conversion unit is obtained between the one electrode of the first pair of electrodes and the another electrode of the third pair of electrodes.

Not shown in figures, further more photoelectric conversion units can be formed by laminating a forth photoelectric conversion unit made of a Ge semiconductor or the like similarly. For example, a Ge semiconductor having a band gap energy of approximately 0.2 eV can generate electric voltage by absorbing light having a wavelength of approximately 2,480 to 6,200 nm. As a result, light of wider range of wavelength can be converted into electric power. Although three photoelectric conversion units are laminated in FIG. 1, even only two photoelectric conversion units are laminated, a photoelectric conversion unit of a desired range of wavelength can be obtained, while electrodes of both units at a junction surface are formed easily, since they can be laminated even if their lattice constants are different, because a direct crystal growth is not applied.

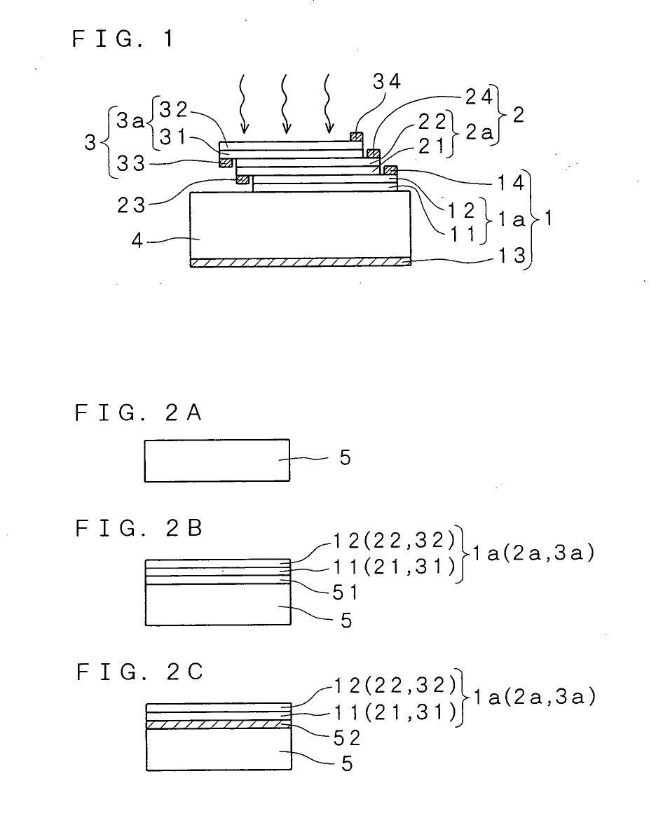

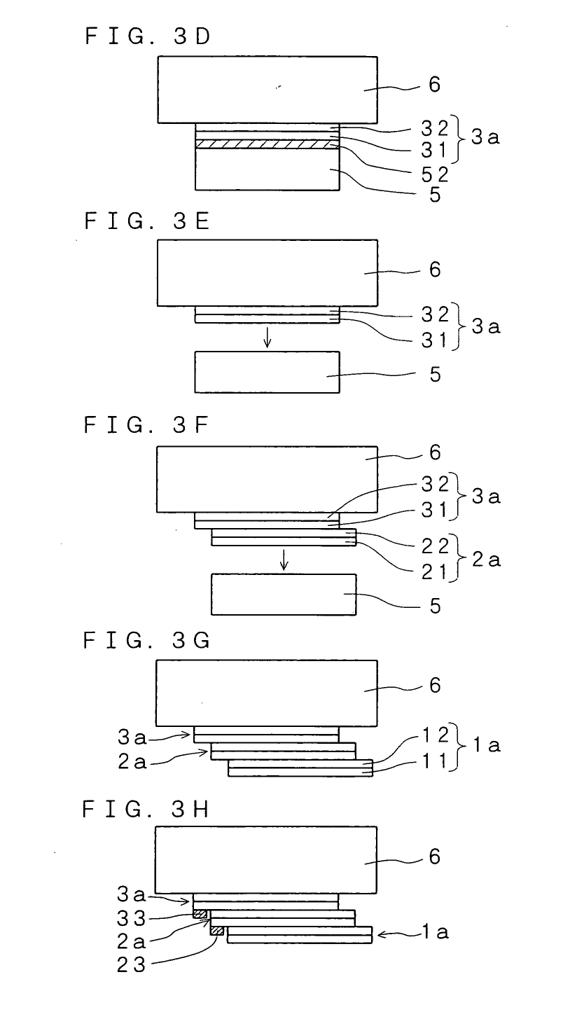

Subsequently, an explanation will be given below of a method for manufacturing the laminate type thin-film solar cell according to the present invention in reference to FIGS. 2A to 2C and FIGS. 3D to 3H.

Firstly, as shown in FIGS. 2A and 2B, a third semiconductor lamination portion 3a is formed by forming semiconductor layers 31 and 32 which compose a third photoelectric conversion unit 3 through an easily-oxidized compound layer 511, for example, AlᵤGa₁₋ᵤAs (0.5≦u≦1, for example u=1) layer or AlᵥIn₁₋ᵥAs (0.5≦v≦1) layer, with matching in crystal structure to a substrate 5, made of for example GaAs, for growing semiconductor layers, on the substrate 5. Conductivity type of the substrate 5 for growing semiconductor layers may be an n-type or a p-type. An AlAs layer 51 is formed in a thickness of, for example, approximately 0.01 to 0.5 μm and In_{0.49}(Ga_{y}Al_{1-y})_{0.51}P (for example, y=1) layers 31 and 32 of, for example, a p-type and an n-type are formed thereon in a thickness of 0.5 to 3 μm in order. An order of formation of the p-type and n-type layers is not limited.

Subsequently, the substrate 5 on which semiconductor layers are formed is charged in an oxidizing furnace having an atmosphere of steam, and are processed by an oxidizing treatment at a temperature of approximately 400 to 500° C. and for a period of approximately 1 to 20 hours, in order to obtain an Al₂O₃ layer 52 by oxidizing the AlAs layer 51 as shown in FIG. 2C. Here, as a ratio of Al in compound crystal is very high in the AlAs layer 51, the AlAs layer 51 is significantly oxidized in the oxidizing treatment, but other In_{0.49}Ga_{0.51}p layers 31 and 32 are hardly oxidized and receive no influence. In this sense, in place of the AlAs layer, an AlGaAs layer containing Ga of a little makes no problem, Al(P, Sb) (a compound of Al and at least one of Pb and Sb, the same applies hereinafter), InAl(As, p, Sb) or InGaAl(As, P, Sb) may be employed. A point of the layer 51 is that an In_{0.49}Ga_{0.51}p layer or the like can be grown thereon by the epitaxial growth technique and that the layer can be oxidized faster than the epitaxially grown layer. The treatment may be performed in or after sticking a next semiconductor lamination portion.

Thereafter, as shown in FIGS. 3D and 3E, after sticking a top face of the third semiconductor lamination portion 3a on a temporary substrate 6 made of, for example, Si or the like, the substrate 5 for growing semiconductor layers is removed by dissolving the oxidized layer 52, Al₂O₃ layer, formed by oxidizing described above. The third semiconductor lamination portion 3a is stuck by fixing with a fixing jig after drying the lamination portion 3a in order to remove from the temporary substrate 6 easily. In dissolving the Al₂O₃ layer 52, only Al₂O₃ layer 52 is dissolved by dipping in ammonia, but other semiconductor lamination portion and the substrate 5 for growing semiconductor layers make no change, therefore, the substrate 5 for growing semiconductor layers can be removed. Besides, hydrofluoric acid or the like can be used for dissolving only the oxidized layer.

Thereafter, the second semiconductor lamination portion 2a (21, 22) made of GaAs for the second photoelectric conversion unit is formed on the substrate 5 for growing semiconductor layers through an AlAs layer 51 by the epitaxial growth technique and is stuck on the third semiconductor lamination portion 3a after oxidizing the AlAs layer 51. Here, as shown in FIG. 3F, the second semiconductor lamination portion 2a is stuck on the third semiconductor lamination portion 3a with a little displacement to make a level difference. In this sticking, different from sticking on the temporary substrate 6, sticking is performed by melting wafer or melting SiO₂ by heating or the like to get sure sticking. Laminating structure of the third semiconductor lamination portion 3a and the second lamination portion 2a is formed by removing the substrate 5 for growing semiconductor layers in the same manner described above.

In the same manner of growing and sticking the second semiconductor lamination portion 2a, the first semiconductor lamination portion 1a which is made of InₓGa₁₋ₓAs (x=0.7) layers 11 and 12 formed on the substrate 5 for growing semiconductor layers, is stuck on the second semiconductor lamination portion 2a with a slight displacement. Thereafter, by removing the substrate 5 for growing semiconductor layers, the first to third semiconductor lamination portions 1a, 2a and 3a are laminated on the temporary substrate 6 as shown in FIG. 3G. Here, since the AlAs(AlᵤGa₁₋ᵤAs) layer 51 keeps the lattice matching with the GaAs substrate 5, the crystal structure of the semiconductor layers grown is maintained. On the contrary, although InₓGa₁₋ₓAs (x=0.7) layer has a lattice constant different from that of the GaAs substrate, it can be formed on the GaAs substrate with a super thin film technique.

Thereafter, as shown in FIG. 3H, the each of one electrode 23 and 33 of the second and third pair of electrode is formed on exposed surfaces (p-type semiconductor layers 21 and 31) of the second semiconductor lamination portion 2a and the third semiconductor lamination portion 3a, by forming a metal film made of Au or the like in a thickness of approximately 0.2 to 1 μm, from a side of the first semiconductor lamination portion 1a by the vacuum evaporation technique or the like after covering a surface of the first semiconductor lamination portion 1a with a resist film or the like. Here, the one electrode 13 of the first pair of electrodes may be formed by forming a metal film on the entire surface of the first semiconductor lamination portion 1a without coating a mask, or on a part of the surface using a mask making a partially exposed area. The electrodes 22 and 23 can be allowed to contact with semiconductor layers of adjacent the first semiconductor lamination portion 1a and the second semiconductor lamination portion 2a, if the metal films make no short circuit with the p-n junctions.

Thereafter, the surface of the first semiconductor lamination portion 1a is stuck, being fixed with a fixing jig, on the real substrate 4 made of silicon or the like after being cleaned, and the temporary substrate 6 is removed. Then, the another electrode 14, 24 and 34 of the first to third pairs of electrodes are formed on exposed surfaces (n-type semiconductor layers 12, 22 and 32) of the first to third semiconductor lamination portions 1a, 2a and 3a, by forming a metal film made of Au or the like in a thickness of approximately 0.2 to 1 μm, from a side of the third semiconductor lamination portion 3a by the vacuum evaporation technique or the like after forming a mask so as to expose a part of the exposed surface of the third semiconductor lamination portion 3a. Then the laminate type thin film solar cell having a structure shown in FIG. 1 can be obtained by forming the one electrode 13 of the first pair of electrodes on a back surface of the real substrate 4 by the same vacuum evaporation technique.

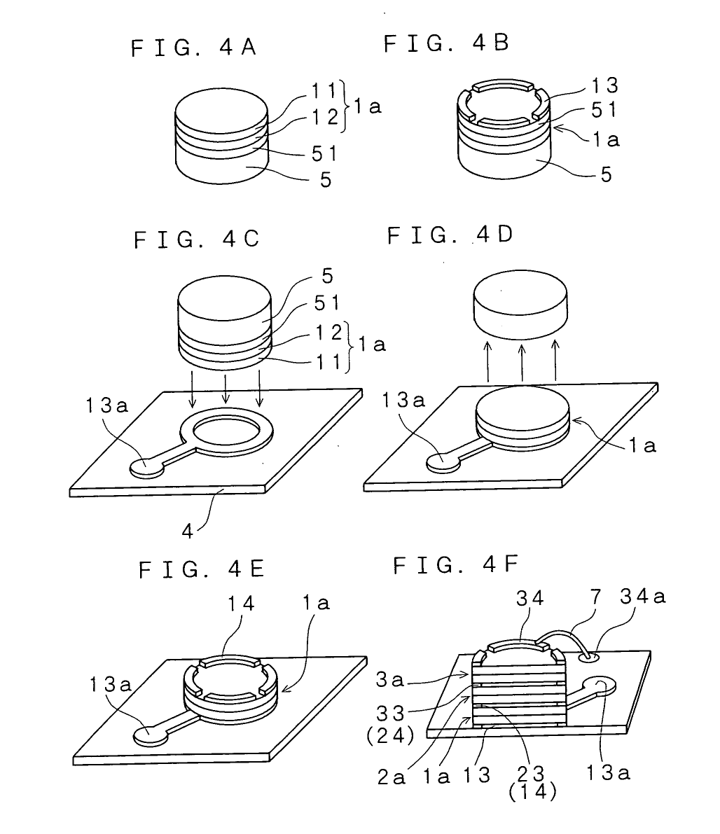

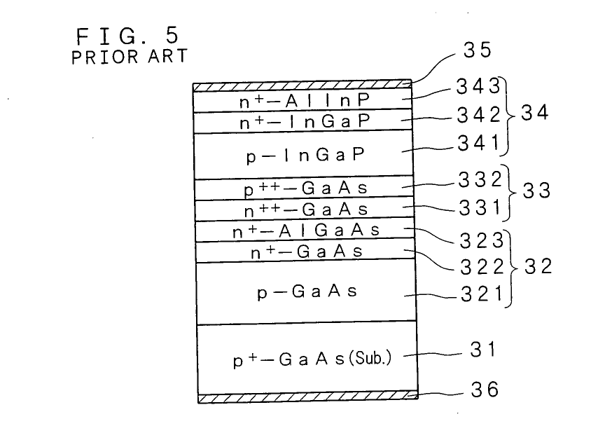

FIGS. 4A to 4F are figures explaining the manufacturing process of other embodiments of the laminate type thin film solar cell according to the present invention. Firstly, in a same manner as shown in FIGS. 2A to 2C (an order of a p-type layer and an n-type layer of semiconductor layers is reversed, but the order is not limited to this), a first semiconductor lamination portion 1a (12, 11) is formed, which composes a first photoelectric conversion unit, through an easily-oxidized compound layer (for example AlAs layer) 51 with matching in crystal structure to a substrate 5 for growing semiconductor layers on the substrate 5. Then, the one electrode 13 of the first pair of electrodes is formed on a part of the first semiconductor lamination portion 1a (cf. FIGS. 4A and 4B). As the electrode 13 is located on a face opposite to a face irradiated by light, the electrode 13 may be formed not only on an outer periphery, but also on an entire surface, on entire surrounding only of an outer periphery, or on a part of an outer periphery as shown in figures.

As shown in FIG. 4C, a top face of the first semiconductor lamination portion 1a is stuck on the real substrate such that an electrode terminal 13a formed on the real substrate connects to the one electrode 13 of the first pair of electrodes of the first photoelectric conversion unit. As shown in FIG. 4D, the substrate 5 for growing is removed by ammonia, after oxidizing AlAs layer 51 in same manner described above. Sticking is performed by melting semiconductor or SiO₂ by heating. An AlAs layer 51 may be oxidized before sticking.

Thereafter, as shown in FIG. 4E, the another electrode 14 of the first pair of electrodes is formed, by the vacuum evaporation technique, on an outer periphery of a surface of the n-type layer 12 of the first semiconductor lamination portion 1a exposed by removing the substrate for growing semiconductor layers. The electrode 14 is not necessary formed on the entire surroundings of the outer periphery but formed partially as shown in figures. It is preferable that an area of the electrode is small, because an area of a surface receiving light increases.

Thereafter the second semiconductor lamination portion 2a for the second photoelectric conversion unit and the third semiconductor lamination portion 3a for the second photoelectric conversion unit are stuck so as to connect an electrode of the n-type layer and an electrode of the p-type layer (in series connection). By connecting another electrode 34 of the third pair of electrodes to an electrode terminal 34a formed on the surface of the real substrate 4 with wiring 7, a total electric power generated by the first to third units can be obtained between the one electrode 13a and the other electrode 34a. As a number of the photoelectric conversion units laminated is not limited to three as described above, the number may be two such as in the example described above, four or more. In addition, in this example an insulating substrate, or a semiconductor substrate or a conductive substrate on which an insulating film is formed, is used as a real substrate. A process except forming the substrate and the electrode is same as in the above-described example.

In the above-described example, the first and second photoelectric units or the like formed separately are stuck on an insulating substrate or an insulating film formed on the substrate, but the one electrode 13 of the first pair of electrodes can be formed on a back surface of this substrate as one electrode terminal 13a, by forming the first photoelectric conversion unit 1 on a semiconductor substrate directly, and by treating this substrate as the above-described substrate. In this case, the processes shown in FIGS. 4A to 4D are not necessary for the first photoelectric conversion unit 1, but necessary for units from the second photoelectric conversion unit.

By the method according to the present invention, a plurality of photoelectric conversion units are laminated by sticking semiconductor lamination portions composing photoelectric conversion units, semiconductor lamination portions can be stuck with a slight displacement, and electrodes can be formed on a part being exposed by level differences. As shown in FIGS. 4B to 4F, lamination can be performed while forming electrodes in each unit. In any manner, both electrodes can be easily formed on each unit. As a result, as electrodes can be connected freely by wire bonding or connected each other directly, light of wide range of wavelength can be converted into photo-electromotive force and a solar cell of high efficiency can be obtained by connecting electrodes so as to make series connection of each photoelectric unit.

Furthermore, by the method according to the present invention, since a plurality of photoelectric conversion units are laminated by sticking, semiconductor lamination portion in which lattice defects hardly occurs can be laminated without limitation in selecting semiconductor material, and photoelectric conversion units operating in a desired range of wavelength can be laminated even in case of laminating semiconductor layers having significantly different band gap energies and different lattice constants to convert light of wide range of wavelength.

As a result of this, according to the present invention, a semiconductor lamination portion converting light of a desired range of wavelength can be laminated by desired number of layers and a laminate type thin-film solar cell having very high efficiency can be obtained.

### INDUSTRIAL APPLICABILITY

A laminate type thin-film solar cell according to the present invention can be widely used for devices from mobile devices to electric devices of all kinds such as clean electric-power sources which never release CO₂ and further for electric-power sources used in space devices.

1. A laminate type thin-film solar cell comprising:
a substrate;
a first photoelectric conversion unit formed on the substrate, the first photoelectric conversion unit comprising a first semiconductor lamination portion made of a semiconductor having a first band gap energy and a first pair of electrodes which are formed on at least a part of each of both surfaces of the first semiconductor lamination portion and connected electrically thereto; and
a second photoelectric conversion unit formed on the first photoelectric conversion unit, the second photoelectric conversion unit comprising a second semiconductor lamination portion made of a semiconductor having a second band gap energy and a second pair of electrodes which are formed on at least a part of each of both surfaces of the second semiconductor lamination portion and connected electrically thereto.

2. The laminate type thin-film solar cell according to claim 1, wherein one of each of the first and second pairs of electrodes is formed on a part of a semiconductor layer of each of the first and second photoelectric conversion units, the part being exposed by the level difference which is formed by sticking the first and second photoelectric conversion units with a displacement.

3. The laminate type thin-film solar cell according to claim 1, wherein the first and second pairs of electrodes are formed on surroundings of both surfaces of each of the first and second photoelectric conversion units, and the first and second photoelectric conversion units are stuck, by putting one on the other, at faced parts of one of the first pair of electrodes and one of the second pair of electrodes so as to be connected electrically in series.

4. The laminate type thin-film solar cell according to claim 1, further comprising:
a third photoelectric conversion unit formed on a surface of the second photoelectric conversion unit, the third photoelectric conversion unit comprising a third semiconductor lamination portion made of a semiconductor having a third band gap energy and a third pair of electrodes which are formed on at least a part of each of both surfaces of the third semiconductor lamination portion and connected electrically thereto; and
a forth photoelectric conversion unit formed on a surface of the third photoelectric conversion unit, the forth photoelectric conversion unit comprising a forth semiconductor lamination portion made of a semiconductor having a forth band gap energy and a forth pair of electrodes formed on at least a part of each of both surfaces of the forth semiconductor lamination portion and connected electrically thereto.

5. The laminate type thin-film solar cell according to claim 3,
wherein the substrate is formed of a semiconductor which composes the first photoelectric conversion unit, and one or more photoelectric conversion units including the second photoelectric conversion unit are stuck on the first photoelectric conversion unit so as to be connected in series; and
wherein an electrode formed on a back surface of the substrate and an electrode formed on a top surface of the photoelectric conversion units stuck are employed as electrode terminals.

6. The laminate type thin-film solar cell according to claim 3, wherein two or more photoelectric conversion units including the first and second photoelectric conversion units are stuck in a series connection, on a surface of an insulating substrate, or an insulating film which is formed on a surface of a semiconductor substrate or a conductive substrate, and a terminal of one electrode of the first photoelectric conversion unit and a terminal of an electrode formed on a top surface of the stuck photoelectric conversion units are formed on a surface of the insulating substrate or the insulating film.

7. A method for manufacturing a laminate type thin-film solar cell comprising the steps of:
(a) forming a second semiconductor lamination portion, which composes a second photoelectric conversion unit, through an easily-oxidized compound layer with matching in crystal structure to a substrate for growing semiconductor layers on the substrate;
(b) sticking only the second semiconductor lamination portion on a temporary substrate, by sticking a top face of the second semiconductor lamination portion on a temporary substrate and by removing the substrate for growing by dissolving an oxidized layer formed by oxidizing the easily-oxidized compound layer;
(c) forming a first semiconductor lamination portion, which composes the first photoelectric conversion unit through an easily-oxidized compound layer with matching in crystal structure to a substrate for growing semiconductor layers on the substrate;
(d) sticking only the first semiconductor lamination portion left, by sticking the first semiconductor lamination portion on a surface of the second semiconductor lamination portion stuck on the temporary substrate, so as to expose a part of the second semiconductor lamination portion by displacement and by removing the substrate for growing by dissolving an oxidized layer formed by oxidizing the easily-oxidized compound layer;
(e) forming an electrode on the exposed surface of at least the second semiconductor lamination portion by depositing a metal film from a top surface side of the first semiconductor lamination portion;
(f) removing the temporary substrate after sticking a real substrate on a surface of the first semiconductor lamination portion; and
(g) forming an electrode on an exposed surface, which surface is a contacted surface of the first semiconductor lamination portion contacted with the second semiconductor lamination portion, by depositing a metal film from a surface side of the second semiconductor lamination portion.

8. A method for manufacturing a laminate type thin-film solar cell comprising the steps of:
(a) forming a first semiconductor lamination portion, which composes a first photoelectric conversion unit, through an easily-oxidized compound layer with matching in crystal structure to a substrate for growing semiconductor layers on the substrate, and forming one of the first pair of electrodes on a part of the first semiconductor lamination portion;
(b) sticking only the first semiconductor lamination portion on a real substrate, by sticking a top face of the first semiconductor lamination portion on the real substrate such that an electrode formed on the real substrate connects to the one of the first pair of electrodes of the first photoelectric conversion unit, and by removing the substrate for growing by dissolving an oxidized layer formed by oxidizing the easily-oxidized compound layer;
(c) forming a second semiconductor lamination portion, which composes a second photoelectric conversion unit through an easily-oxidized compound layer with matching in crystal structure to a substrate for growing semiconductor layers on the substrate, and forming one of a second pair of electrodes on a part of a surface of the second semiconductor lamination portion;
(d) sticking only the second semiconductor lamination portion, by forming another electrode of the first pair of electrodes on a part of an exposed surface of the first semiconductor lamination portion stuck on the real substrate, by sticking a top surface of the second semiconductor lamination portion such that the another electrode of the first pair of electrodes connects to the one of the second pair of electrodes of the second semiconductor lamination portion, and by removing the substrate for growing by dissolving an oxidized layer formed by oxidizing the easily-oxidized compound layer; and
(e) forming another electrode of the second pair of electrodes on a part of an exposed surface of the second semiconductor lamination portion on the real substrate.

9. The method for manufacturing the laminate type thin-film solar cell according to claim 7, wherein the easily-oxidized compound layer is made of a material represented by AlᵤGa₁₋ᵤAs (0.5≦u≦1) or AlᵥIn₁₋ᵥAs (0.5≦v≦1).

10. The method for manufacturing the laminate type thin-film solar cell according to claim 8, wherein the easily-oxidized compound layer is made of a material represented by AlᵤGa₁₋ᵤAs (0.5≦u≦1) or AlᵥIn₁₋ᵥAs (0.5≦v≦1).
